(19) United States
(12) Patent Application Publication
(10) Pub. No.: US 2005/0048700 A1
(43) Pub. Date: Mar. 3, 2005

(54) No-flow underfill material having low coefficient of thermal expansion and good solder ball fluxing performance

(76) Inventors: Slawomir Rubinsztajn, Niskayuna, NY (US); Sandeep Tonapi, Niskayuna, NY (US); John Campbell, Clifton Park, NY (US); Ananth Prabhakumar, Schenectady, NY (US)

Correspondence Address: GE Global Research, Docket Room K-1/4A59, One Research Circle, Niskayuna, NY, 12309, US

(21) Appl. No.: 10/653,371

(22) Filed: Sep. 2, 2003

(51) Int. Cl. H01L 21/56; B32B 27/38; C08L 63/00

(52) U.S. Cl. 438/127; 428/413; 523/443

(57) ABSTRACT

A no-flow underfill composition comprising an epoxy resin in combination with epoxy hardener and optional reagents and a filler of a functionalized colloidal silica having a particle size ranging from about 1 nm to about 250 nm. The colloidal silica is functionalized with at least one organoalkoxysilane functionalization agent and subsequently functionalized with at least one capping agent. The epoxy hardener includes anhydride curing agents. The optional reagents include cure catalyst and hydroxyl-containing monomer. The adhesion promoters, flame retardants and defoaming agents may also be added to the composition. Further embodiments of the present disclosure include packaged solid state devices comprising the underfill compositions.

### BACKGROUND OF THE INVENTION

The present disclosure is related to functionalized colloidal silica and its use in underfill materials utilized in electronic devices. More particularly, the present disclosure is related to organic dispersions of functionalized colloidal silica.

Demand for smaller and more sophisticated electronic devices continues to drive the electronic industry towards improved integrated circuit packages that are capable of supporting higher input/output (I/O) density as well as possessing enhanced performance with smaller die areas. While flip chip technology has been utilized to respond to these demanding requirements, a weak point of the flip chip construction is the significant mechanical stress experienced by solder bumps during thermal cycling. This stress is due to the coefficient of thermal expansion (CTE) mismatch between silicon die and substrate that, in turn, causes mechanical and electrical failures of the electronic devices.

Currently, capillary underfill is used to fill gaps between the silicon chip and substrate and improves the fatigue life of solder bumps. Unfortunately, many encapsulant compounds utilized in such underfill materials suffer from the inability to fill small gaps (50-100 μm) between the chip and substrate due to high filler content and high viscosity of the encapsulant.

While a new process, no-flow underfill, has been developed to address these issues, the use of resins filled with conventional fillers in these processes remains problematic. In the case of the no-flow process, application of the underfill resin is performed before die placement, a process change that avoids the time delay associated with wicking of the material under the die. In no-flow underfill applications, it is also desirable to avoid entrapment of filler particles during solder joint formulation. Thus, there remains a need to find a material that has a high glass transition temperature, low coefficient of thermal expansion and ability to form reliable solder joints during a reflow process such that it can fill small gaps between chips and substrates.

### BRIEF DESCRIPTION OF THE INVENTION

The present disclosure provides a composition useful as an underfill resin comprising an epoxy resin with epoxy hardener to which a functionalized colloidal silica has been added. The compositions of the present disclosure provide good solder ball fluxing, a large reduction in the coefficient of thermal expansion, and an advantageous increase in glass transition temperature. Preferably, the composition of the present invention is used as a no-flow underfill resin.

In one embodiment, the colloidal silica is functionalized with at least one organoalkoxysilane functionalization agent. In another embodiment, a dispersion can be formed by adding at least one capping agent and at least one epoxy monomer to the functionalized silica. The composition may be used as an encapsulant in a packaged solid state device.

### DETAILED DESCRIPTION OF THE INVENTION

It has been found that the use of at least one epoxy resin, at least one functionalized colloidal silica, at least one hardener, at least one cure catalyst, and optional reagents provides a curable epoxy formulation with a low viscosity of the total composition before cure and whose cured parts have a low coefficient of thermal expansion (CTE). “Low viscosity of the total composition before cure” typically refers to a viscosity of the epoxy formulation in a range between about 50 centipoise and about 100,000 centipoise and preferably, in a range between about 1000 centipoise and about 20,000 centipoise at 25° C. before the composition is cured. “Low coefficient of thermal expansion” as used herein refers to a cured total composition with a coefficient of thermal expansion lower than that of the base resin as measured in parts per million per degree centigrade (ppm/° C.). Typically, the coefficient of thermal expansion of the cured total composition is below about 50 ppm/° C.

Epoxy resins are curable monomers and oligomers that are blended with the functionalized colloidal silica. Epoxy resins include any organic system or inorganic system with an epoxy functionality. The epoxy resins useful in the present disclosure include those described in “Chemistry and Technology of the Epoxy Resins,” B. Ellis (Ed.) Chapman Hall 1993, New York and “Epoxy Resins Chemistry and Technology,” C. May and Y. Tanaka, Marcel Dekker 1972, New York. Epoxy resins that can be used for the present disclosure include those that could be produced by reaction of a hydroxyl, carboxyl or amine containing compound with epichlorohydrin, preferably in the presence of a basic catalyst, such as a metal hydroxide, for example sodium hydroxide. Also included are epoxy resins produced by reaction of a compound containing at least one and preferably two or more carbon-carbon double bonds with a peroxide, such as a peroxyacid.

Preferred epoxy resins for use in accordance with the present disclosure are cycloaliphatic, aliphatic, and aromatic epoxy resins. Aliphatic epoxy resins include compounds that contain at least one aliphatic group and at least one epoxy group. Examples of aliphatic epoxies include butadiene dioxide, dimethylpentane dioxide, diglycidyl ether, 1,4-butanedioldiglycidyl ether, diethylene glycol diglycidyl ether, and dipentene dioxide.

Cycloaliphatic epoxy resins are well known to the art and, as described herein, are compounds that contain at least about one cycloaliphatic group and at least one oxirane group. More preferred cycloaliphatic epoxies are compounds that contain about one cycloaliphatic group and at least two oxirane rings per molecule. Specific examples include 3-cyclohexenylmethyl -3-cyclohexenylcarboxylate diepoxide, 2-(3,4-epoxy)cyclohexyl-5,5-spiro-(3,4-epoxy)cyclohexane-m-dioxane, 3,4-epoxycyclohexylalkyl-3,4-epoxycyclohexanecarboxylate, 3,4-epoxy-6-methylcyclohexylmethyl-3,4-epoxy-6-methylcyclohexanecarboxylate, vinyl cyclohexanedioxide, bis(3,4-epoxycyclohexylmethyl)adipate, bis(3,4-epoxy-6-methylcyclohexylmethyl)adipate, exo-exo bis(2,3-epoxycyclopentyl) ether, endo-exo bis(2,3-epoxycyclopentyl) ether, 2,2-bis(4-(2,3-epoxypropoxy)cyclohexyl)propane, 2,6-bis(2,3-epoxypropoxycyclohexyl-p-dioxane), 2,6-bis(2,3-epoxypropoxy)norbomene, the diglycidylether of linoleic acid dimer, limonene dioxide, 2,2-bis(3,4-epoxycyclohexyl)propane, dicyclopentadiene dioxide, 1,2-epoxy-6-(2,3-epoxypropoxy)hexahydro-4,7-methanoindane, p-(2,3-epoxy)cyclopentylphenyl-2,3-epoxypropylether, 1-(2,3-epoxypropoxy)phenyl-5,6-epoxyhexahydro-4,7-methanoindane, o-(2,3-epoxy)cyclopentylphenyl-2,3-epoxypropyl ether), 1,2-bis(5-(1,2-epoxy)-4,7-hexahydromethanoindanoxyl)ethane, cyclopentenylphenyl glycidyl ether, cyclohexanediol diglycidyl ether, and diglycidyl hexahydrophthalate. Typically, the cycloaliphatic epoxy resin is 3-cyclohexenylmethyl-3-cyclohexenylcarboxylate diepoxide.

Aromatic epoxy resins may also be used in accordance with the present disclosure. Examples of epoxy resins useful in the present disclosure include bisphenol-A epoxy resins, bisphenol-F epoxy resins, phenol novolac epoxy resins, cresol-novolac epoxy resins, biphenol epoxy resins, biphenyl epoxy resins, 4,4′-biphenyl epoxy resins, polyfunctional epoxy resins, divinylbenzene dioxide, and 2-glycidylphenylglycidyl ether. When resins, including aromatic, aliphatic and cycloaliphatic resins are described throughout the specification and claims, either the specifically-named resin or molecules having a moiety of the named resin are envisioned.

Silicone-epoxy resins of the present disclosure typically have the formula:
MₐM′_{b}D_{c}D′_{d}TₑT′_{f}Q_{g}
where the subscripts a, b, c, d, e, f and g are zero or a positive integer, subject to the limitation that the sum of the subscripts b, d and f is one or greater; where M has the formula:
R¹₃SiO_{1/2},
M′ has the formula:
(Z)R²₂SiO_{1/2},
D has the formula:
R³₂SiO_{2/2},
D′ has the formula:
(Z)R⁴SiO_{2/2},
T has the formula:
R⁵SiO_{3/2},
T′ has the formula:
(Z)SiO_{3/2},
and Q has the formula SiO_{4/2},
where each R¹, R², R³, R⁴, R⁵ is independently at each occurrence a hydrogen atom, C₁₋₂₂ alkyl, C₁₋₂₂ alkoxy, C₂₋₂₂ alkenyl, C₆₋₁₄ aryl, C₆₋₂₂ alkyl-substituted aryl, and C₆₋₂₂ arylalkyl, which groups may be halogenated, for example, fluorinated to contain fluorocarbons such as C₁₋₂₂ fluoroalkyl, or may contain amino groups to form aminoalkyls, for example aminopropyl or aminoethylaminopropyl, or may contain polyether units of the formula (CH₂CHR⁶O)ₖ where R⁶ is CH₃ or H and k is in a range between about 4 and 20; and Z, independently at each occurrence, represents an epoxy group. The term “alkyl” as used in various embodiments of the present disclosure is intended to designate both normal alkyl, branched alkyl, aralkyl, and cycloalkyl radicals. Normal and branched alkyl radicals are preferably those containing in a range between about 1 and about 12 carbon atoms, and include as illustrative non-limiting examples methyl, ethyl, propyl, isopropyl, butyl, tertiary-butyl, pentyl, neopentyl, and hexyl. Cycloalkyl radicals represented are preferably those containing in a range between about 4 and about 12 ring carbon atoms. Some illustrative non-limiting examples of these cycloalkyl radicals include cyclobutyl, cyclopentyl, cyclohexyl, methylcyclohexyl, and cycloheptyl. Preferred aralkyl radicals are those containing in a range between about 7 and about 14 carbon atoms; these include, but are not limited to, benzyl, phenylbutyl, phenylpropyl, and phenylethyl. Aryl radicals used in the various embodiments of the present disclosure are preferably those containing in a range between about 6 and about 14 ring carbon atoms. Some illustrative non-limiting examples of these aryl radicals include phenyl, biphenyl, and naphthyl. An illustrative non-limiting example of a halogenated moiety suitable is trifluoropropyl.

Combinations of the foregoing epoxy monomers and oligomers may also be used in the compositions of the present disclosure.

Colloidal silica is a dispersion of submicron-sized silica (SiO₂) particles in an aqueous or other solvent medium. The colloidal silica contains up to about 85 weight % of silicon dioxide (SiO₂) and typically up to about 80 weight % of silicon dioxide. The particle size of the colloidal silica is typically in a range between about 1 nanometers (nm) and about 250 nm, preferably in a range from about 5 nm to about 150 nm, with a range of from about 5 nm to about 100 nm being most preferred. In one embodiment, the particle size of the colloidal silica is below about 25 nm. The colloidal silica is functionalized with an organoalkoxysilane to form an organofunctionalized colloidal silica.

Organoalkoxysilanes used to functionalize the colloidal silica are included within the formula:
(R⁷)ₐSi(OR⁸)₄₋ₐ,
where R⁷ is independently at each occurrence a C₁₋₁₈ monovalent hydrocarbon radical optionally further functionalized with alkyl acrylate, alkyl methacrylate, epoxide groups or C₆₋₁₄ aryl or alkyl radical, R⁸ is independently at each occurrence a C₁₋₁₈ monovalent hydrocarbon radical or a hydrogen radical, and “a” is a whole number equal to 1 to 3 inclusive. Preferably, the organoalkoxysilanes included in the present disclosure are 2-(3,4-epoxy cyclohexyl)ethyltrimethoxysilane, 3-glycidoxypropyltrimethoxysilane, phenyltrimethoxysilane, and methacryloxypropyltrimethoxysilane. A combination of functionality is also possible.

Typically, the organoalkoxysilane is present in a range between about 1 weight % and about 60 weight % based on the weight of silicon dioxide contained in the colloidal silica with a range of from about 5 weight % to about 30 weight % being preferred.

The functionalization of colloidal silica may be performed by adding the organoalkoxysilane functionalization agent to a commercially available aqueous dispersion of colloidal silica in the weight ratio described above to which an aliphatic alcohol has been added. The resulting composition comprising the functionalized colloidal silica and the organoalkoxysilane functionalization agent in the aliphatic alcohol is defined herein as a pre-dispersion. The aliphatic alcohol may be selected from but not limited to isopropanol, t-butanol, 2-butanol, and combinations thereof. The amount of aliphatic alcohol is typically in a range between about 1 fold and about 10 fold of the amount of silicon dioxide present in the aqueous colloidal silica pre-dispersion.

The resulting organofunctionalized colloidal silica can be treated with an acid or base to adjust the pH. An acid or base as well as other catalysts promoting condensation of silanol and alkoxysilane groups may also be used to aid the functionalization process. Such catalysts include organo-titanate and organo-tin compounds such as tetrabutyl titanate, titanium isopropoxybis(acetylacetonate), dibutyltin dilaurate, or combinations thereof. In some cases, stabilizers such as 4-hydroxy-2,2,6,6-tetramethylpiperidinyloxy (i.e. 4-hydroxy TEMPO) may be added to this pre-dispersion. The resulting pre-dispersion is typically heated in a range between about 50° C. and about 100° C. for a period in a range between about 1 hour and about 5 hours.

The cooled transparent organic pre-dispersion is then further treated to form a final dispersion of the functionalized colloidal silica by addition of curable epoxy monomers or oligomers and optionally, more aliphatic solvent which may be selected from but not limited to isopropanol, 1-methoxy-2-propanol, 1-methoxy-2-propyl acetate, toluene, and combinations thereof. “Transparent” as used herein refers to a maximum haze percentage of 15, typically a maximum haze percentage of 10; and most typically a maximum haze percentage of 3. This final dispersion of the functionalized colloidal silica may be treated with acid or base or with ion exchange resins to remove acidic or basic impurities. This final dispersion of the functionalized colloidal silica is then concentrated under a vacuum in a range between about 0.5 Torr and about 250 Torr and at a temperature in a range between about 20° C. and about 140° C. to substantially remove any low boiling components such as solvent, residual water, and combinations thereof to give a transparent dispersion of functionalized colloidal silica in a curable epoxy monomer, herein referred to as a final concentrated dispersion. Substantial removal of low boiling components is defined herein as removal of at least about 90% of the total amount of low boiling components.

In some instances, the pre-dispersion or the final dispersion of the functionalized colloidal silica may be further functionalized. Low boiling components are at least partially removed and subsequently, an appropriate capping agent that will react with residual hydroxyl functionality of the functionalized colloidal silica is added in an amount in a range between about 0.05 times and about 10 times the amount of silicon dioxide present in the pre-dispersion or final dispersion. Partial removal of low boiling components as used herein refers to removal of at least about 10% of the total amount of low boiling components, and preferably, at least about 50% of the total amount of low boiling components. An effective amount of capping agent caps the functionalized colloidal silica and capped functionalized colloidal silica is defined herein as a functionalized colloidal silica in which at least 10%, preferably at least 20%, more preferably at least 35%, of the free hydroxyl groups present in the corresponding uncapped functionalized colloidal silica have been functionalized by reaction with a capping agent. Capping the functionalized colloidal silica effectively improves the cure of the total curable epoxy formulation by improving room temperature stability of the epoxy formulation. Formulations which include the capped functionalized colloidal silica show much better room temperature stability than analogous formulations in which the colloidal silica has not been capped.

Exemplary capping agents include hydroxyl reactive materials such as silylating agents. Examples of a silylating agent include, but are not limited to hexamethyidisilazane (HMDZ), tetramethyidisilazane, divinyltetramethyldisilazane, diphenyltetramethyldisi lazane, N-(trimethylsilyl)diethylamine, 1-(trimethylsi lyl)imidazole, trimethylchlorosilane, pentamethylchlorodisi loxane, pentamethyldisiloxane, and combinations thereof. The transparent dispersion is then heated in a range between about 20° C. and about 140° C. for a period of time in a range between about 0.5 hours and about 48 hours. The resultant mixture is then filtered. If the pre-dispersion was reacted with the capping agent, at least one curable epoxy monomer is added to form the final dispersion. The mixture of the functionalized colloidal silica in the curable monomer is concentrated at a pressure in a range between about 0.5 Torr and about 250 Torr to form the final concentrated dispersion. During this process, lower boiling components such as solvent, residual water, byproducts of the capping agent and hydroxyl groups, excess capping agent, and combinations thereof are substantially removed.

In order to form the total curable epoxy formulation, an epoxy hardener such as carboxylic acid-anhydride, a phenolic resin, or an amine epoxy hardener is added. Optionally, curing agents such as anhydride curing agents and an organic compound containing hydroxyl moiety are added with the epoxy hardener.

Exemplary anhydride curing agents typically include methyl hexahydrophthalic anhydride (MHHPA), methyltetrahydrophthalic anhydride, 1,2-cyclohexanedicarboxylic anhydride, bicyclo[2.2.1]hept-5-ene-2,3-dicarboxylic anhydride, methylbicyclo[2.2.1]hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and the like, and mixtures thereof. Combinations comprising at least two anhydride curing agents may also be used. Illustrative examples are described in “Chemistry and Technology of the Epoxy Resins” B. Ellis (Ed.) Chapman Hall, New York, 1993 and in “Epoxy Resins Chemistry and Technology”, edited by C. A. May, Marcel Dekker, New York, 2nd edition, 1988.

Examples of organic compounds utilized as the hydroxyl-containing monomer include alcohols, alkane diols and triols, and phenols. Preferred hydroxyl-containing compounds include high boiling alkyl alcohols containing one or more hydroxyl groups and bisphenols. The alkyl alcohols may be straight chain, branched or cycloaliphatic and may contain from 2 to 24 carbon atoms. Examples of such alcohols include, but are not limited to, ethylene glycol; propylene glycol, i.e., 1,2- and 1,3-propylene glycol; 2,2-dimethyl-1,3-propane diol; 2-ethyl, 2-methyl, 1,3-propane diol; 1,3- and 1,5-pentane diol; dipropylene glycol; 2-methyl-1,5-pentane diol; 1,6-hexane diol; dimethanol decalin, dimethanol bicyclo octane; 1,4-cyclohexane dimethanol and particularly its cis- and trans-isomers; triethylene glycol; 1,10-decane diol, polyol-based polyoxyalkylenes, glycerol; and combinations of any of the foregoing. Further examples of alcohols include bisphenols.

Some illustrative, non-limiting examples of bisphenols include the dihydroxy-substituted aromatic hydrocarbons disclosed by genus or species in U.S. Pat. No. 4,217,438. Some preferred examples of dihydroxy-substituted aromatic compounds include 4,4′-(3,3,5-trimethylcyclohexylidene)-diphenol; 2,2-bis(4-hydroxyphenyl)propane (commonly known as bisphenol A); 2,2-bis(4-hydroxyphenyl)methane (commonly known as bisphenol F); 2,2-bis(4-hydroxy-3,5-dimethylphenyl)propane; 2,4′-dihydroxydiphenylmethane; bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl)ethane; 1,1-bis(4-hydroxy-2-chlorophenyl)ethane; 2,2-bis(3-phenyl-4-hydroxyphenyl)propane; bis(4-hydroxyphenyl)cyclohexylmethane; 2,2-bis(4-hydroxyphenyl)- 1-phenylpropane; 2,2,2′,2′-tetrahydro-3,3,3′,3′-tetramethyl-1,1′-spirobi[1H-indene]-6,6′-diol (SBI); 2,2-bis(4-hydroxy-3-methylphenyl)propane (commonly known as DMBPC); resorcinol; and C₁₋₃ alkyl-substituted resorcinols.

Most typically, 2,2-bis(4-hydroxyphenyl)propane and 2,2-bis(4-hydroxyphenyl)methane are the preferred bisphenol compounds. Combinations of organic compounds containing hydroxyl moiety can also be used in the present disclosure.

Cure catalysts can also be added and can be selected from typical epoxy curing catalysts that include, but are not limited to, amines, alkyl-substituted imidazole, imidazolium salts, phosphines, metal salts such as aluminum acetyl acetonate (Al(acac)₃), salts of nitrogen-containing compounds with acidic compounds, and combinations thereof. The nitrogen-containing compounds include, for example, amine compounds, di-aza compounds, tri-aza compounds, polyamine compounds and combinations thereof. The acid compounds include phenol, organo-substituted phenols, carboxylic acids, sulfonic acids and combinations thereof. A preferred catalyst is a salt of a nitrogen-containing compound. One such salt includes, for example, 1,8-diazabicyclo(5,4,0)-7-undecane. The salts of the nitrogen-containing compounds are commercially available, for example, as Polycat SA-1 and Polycat SA-102 from Air Products. Other preferred catalysts include triphenyl phosphine (PPh₃) and alkyl-imidazole.

A reactive organic diluent may also be added to the total curable epoxy formulation to decrease the viscosity of the composition. Examples of reactive diluents include, but are not limited to, 3-ethyl-3-hydroxymethyl-oxetane, dodecylglycidyl ether, 4-vinyl-1-cyclohexane diepoxide, di(Beta-(3,4-epoxycyclohexyl)ethyl)-tetramethyldisiloxane, and combinations thereof.

Adhesion promoters can also be employed with the total curable epoxy formulation such as trialkoxyorganosilanes (e.g. γ-aminopropyltrimethoxysilane, 3-glycidoxypropyltrimethoxysilane, bis(trimethoxysilylpropyl)fumarate), and combinations thereof used in an effective amount which is typically in a range between about 0.01% by weight and about 2% by weight of the total curable epoxy formulation.

Flame retardants may optionally be used in the total curable epoxy formulation of the present disclosure in a range between about 0.5 weight % and about 20 weight % relative to the amount of the total curable epoxy formulation. Examples of flame retardants in the present disclosure include phosphoramides, triphenyl phosphate (TPP), resorcinol diphosphate (RDP), bisphenol-a-diphosphate (BPA-DP), organic phosphine oxides, halogenated epoxy resin (tetrabromobisphenol A) , metal oxide, metal hydroxides, and combinations thereof.

Defoaming agents, dyes, pigments, and the like can also be incorporated into the total curable epoxy formulation.

In one embodiment, it is preferable that the epoxy resin include an aromatic epoxy resin or an alicyclic epoxy resin having two or more epoxy groups in its molecule. The epoxy resins in the composition of the present disclosure preferably have two or more functionalities, and more preferably two to four functionalities. Addition of these materials will provide resin composition with higher glass transition temperatures (Tg).

Preferred difunctional aromatic epoxy resins can be exemplified by difunctional epoxy resins such as bisphenol A epoxies, bisphenol B epoxies, and bisphenol F epoxies. Trifunctional aromatic epoxy resins can be exemplified by triglycidyl isocyanurate epoxy, VG310L manufactured by Mitsui Chemical and the like, and tetrafunctional aromatic epoxy resins can be exemplified by Araldite MTO163 manufactured by Ciba Geigy and the like.

Preferred alicyclic epoxy resins can be exemplified by difunctional epoxies such as Araldite CY179 (Ciba Geigy), UVR6105 (Dow Chemical) and ESPE-3150 (Daicel Chemical), trifunctional epoxies such as Epolite GT300 (Daicel Chemical), and tetrafunctional epoxies such as Epolite GT400 (Daicel Chemical).

In one embodiment, a trifunctional epoxy monomer such as triglylcidyl isocyanurate is added to the composition to provide a multi-functional epoxy resin.

The multi-functional epoxy monomers are included in the resin compositions of the present disclosure in amounts ranging from about 1% by weight to about 50% by weight of the total composition, with a range of from about 5% by weight to about 25% by weight being preferred.

Two or more epoxy resins can be used in combination e.g., a mixture of an alicyclic epoxy and an aromatic epoxy. In this case, it is particularly favorable to use an epoxy mixture containing at least one epoxy resin having three or more functionalities, to thereby form an underfill resin having low CTE, good fluxing performance, and a high glass transition temperature (Tg). The epoxy resin can include a trifunctional epoxy resin, in addition to at least a difunctional alicyclic epoxy and a difunctional aromatic epoxy.

The composition of the present disclosure may by hand mixed but also can be mixed by standard mixing equipment such as dough mixers, chain can mixers, planetary mixers, and the like.

The blending of the present disclosure can be performed in batch, continuous, or semi-continuous mode.

Moreover, the addition of the functionalized colloidal silica to an epoxy resin composition containing hydroxyl monomers and an anhydride in accordance with the present disclosure has been unexpectedly found to provide good solder ball fluxing which, in combination with the large reduction in CTE, can not be achieved with a conventional micron-sized fused silica. The resulting composition possesses both self-fluxing properties and the generation of acidic species during cure which leads to solder ball cleaning and good joint formation.

The use of such a composition will produce chips having enhanced performance and lower manufacturing costs.

In one embodiment, an epoxy composition of the present disclosure possesses both hydroxyl monomers and anhydride monomers. The resulting composition generates acidic species during cure which leads to solder ball cleaning and good joint formation. The resulting composition possesses self-fluxing properties and produces chips having enhanced performance and lower manufacturing costs.

Formulations as described in the present disclosure are dispensable and have utility in devices in electronics such as computers, semiconductors, or any device where underfill, overmold, or combinations thereof is needed. Underfill encapsulant is used to reinforce physical, mechanical, and electrical properties of solder bumps that typically connect a chip and a substrate. Underfilling may be achieved by any method known in the art. The conventional method of underfilling includes dispensing the underfill material in a fillet or bead extending along two or more edges of the chip and allowing the underfill material to flow by capillary action under the chip to fill all the gaps between the chip and the substrate. The preferred method is no-flow underfill. The process of no-flow underfilling includes first dispensing the underfill encapsulant material on the substrate or semiconductor device and second placing a flip chip on the top of the encapsulant and third performing the solder bump reflow to form solder joints and cure underfill encapsulant simultaneously. The material has the ability to fill gaps in a range between about 30 microns and about 250 microns.

In accordance with one aspect of the present disclosure, a packaged solid state device is provided which includes a package, a chip, and an encapsulant comprising the underfill compositions of the present disclosure. In such a case, the encapsulant may be introduced to the chip by processes including capillary underfill, no-flow underfill, and the like. Chips which may be produced using the underfill composition of the present disclosure include semiconductor chips and LED chips.

In a preferred embodiment, the composition of the present disclosure are useful as no-flow underfill materials.

Thus, the underfill composition of the present disclosure, which forms the encapsulant, is typically dispensed using a needle in a dot pattern in the center of the component footprint area. Controlling the amount of no-flow underill is crucial to achieving an ideal fillet size, while avoiding the phenomenon known as “chip-floating”, which results from dispensing an excess of the no-flow underfill. The flip-chip die is placed on the top of the dispensed no-flow underfill using an automatic pick and place machine. The placement force as well as the placement head dwell time are controlled to optimize cycle time and yield of the process. The entire construction is heated to melt solder balls, form solder interconnect and finally cure the underfill resin. The heating operation usually is performed on the conveyor in the reflow oven. The cure kinetics of the no-flow underfill has to be tuned to fit a temperature profile of the reflow cycle. The no-flow underfill has to allow the solder joint formation before the encapsulant reaches a gel point but it has to form a solid encapsulant at the end of the heat cycle.

In a typical manufacturing process of the production of flip-chip devices, the no-flow underfill can be cured by two significantly different reflow profiles. The first profile is referred to as the “plateau” profile, which includes a soak zone below the melting point of the solder. The second profile, referred to as the “volcano” profile, raises the temperature at a constant heating rate until the maximum temperature is reached. The maximum temperature during a cure cycle can range from about 200° C. to about 260° C. The maximum temperature during the reflow strongly depends on the solder composition and has to be about 10° C. to about 40° C. higher than the melting point of the solder balls. The heating cycle is between about 3 to about 10 minutes, and more typically is from about 4 to about 6 minutes. Optionally, the cured encapsulants can be post-cured at a temperature ranging from about 100° C. to about 180° C., more typically from about 140° C. to about 160° C. over a period of time ranging from about 1 hour to about 4 hours.

In order that those skilled in the art will be better able to practice the present disclosure, the following examples are given by way of illustration and not by way of limitation.

### EXAMPLE 1

Preparation of functionalized colloidal silica pre-dispersions. A pre-dispersion 1 of functionalized colloidal silica was prepared using the following procedure. A mixture of aqueous colloidal silica (465 grams (g) available from Nalco as Nalco 1034A containing about 34 wt % silica), isopropanol (800 g) and phenyltrimethoxy silane (56.5 g) was heated and stirred at 60-70° C. for 2 hours to give a clear suspension. The resulting pre-dispersion 1 was cooled to room temperature and stored in a glass bottle.

A pre-dispersion 2 functionalized colloidal silica was prepared using the following procedure. A mixture of aqueous colloidal silica (465 grams (g); available from Nalco as Nalco 1034A containing about 34 wt % silica), isopropanol (800 g) and phenyltrimethoxy silane (4.0 g) was heated and stirred at 60-70° C. for 2 hours to give a clear suspension. The resulting pre-dispersion 2 was cooled to room temperature and stored in a glass bottle.

### EXAMPLE 2

Preparation of resin 1 containing stabilized functionalized colloidal silica. A 250-milliliter (ml) flask was charged with 100 g of the colloidal silica pre-dispersion 1 from Example 1, 50 g of 1-methoxy-2-propanol (Aldrich) as solvent and 0.5 g of crosslinked polyvinylpyridine. The mixture was stirred at 70° C. After 1 hour the suspension was blended with 50 g of 1-methoxy-2-propanol and 2 g Celite® 545 (a commercially available diatomaceous earth filtering aid), cooled down to room temperature and filtered. The resulting dispersion of functionalized colloidal silica was blended with 15.15 g of 3,4-epoxycyclohexylmethyl-3,4-epoxycyclohexane carboxylate (UVR6105 from Dow Chemical Company) and vacuum stripped at 75° C. at 1 mmHg to constant weight to yield 31.3 g of a viscous liquid resin (Resin 1).

### EXAMPLE 3

Preparation of resin 2 containing capped functionalized colloidal silica. A round bottom flask was charged with 100 g of the colloidal silica pre-dispersion 2 from Example 1 and 100 g of 1-methoxy-2-propanol. 100 g of the total mixture was distilled off at 60° C. and 50 Torr. 2 g of hexamethyldisilazane (HMDZ) was added drop-wise to the concentrated dispersion of functionalized colloidal silica. The mixture was stirred at 70° C. for 1 hour. After 1 hour, Celite® 545 was added to the flask, the mixture was cooled to room temperature and filtered. The clear dispersion of functionalized colloidal silica was blended with 14 g of UVR6105 (Dow Chemical Company) and vacuum stripped at 75° C. at 1 mmHg to constant weight to yield 28 g of viscous liquid resin (Resin 2).

### EXAMPLE 4

Preparation of resin 3 containing functionalized colloidal silica. A round bottom flask was charged with 100 g of the colloidal silica pre-dispersion 1 from Example 1, 50 g of 1-methoxy-2-propanol (Aldrich) as solvent and 0.5 g of crosslinked polyvinylpyridine. The mixture was stirred at 70° C. After 1 hour the suspension was blended with 50 g of 1-methoxy-2-propanol and 2 g Celite® 545 (a commercially available diatomaceous earth filtering aid), cooled down to room temperature and filtered. The resulting dispersion of functionalized colloidal silica was blended with 10 g of 3,4-epoxycyclohexylmethyl-3,4-epoxycyclohexane carboxylate (UVR6105 from Dow Chemical Company) and 3.3 g of bisphenol-F epoxy resins (RSL-1739 from Resolution Performance Product) vacuum stripped at 75° C. at 1 mmHg to constant weight to yield 29.4 g of a viscous liquid resin (Resin 3).

### EXAMPLE 5

Preparation of curable epoxy formulations. The functionalized colloidal silica resins of Examples 2, 3 and 4 were blended separately at room temperature with desired amount of 4-methyl-hexahydrophthalic anhydride (MHHPA) (Aldrich) (see Tables below). Subsequently desired amounts of catalyst and optional additives as set forth in the Tables below were added at room temperature. The formulations were blended at room temperature for approximately 10 minutes after which time the formulation was degassed at room temperature for 20 minutes. Cure of the blended composition was accomplished in two stages: first passing the blended composition through a reflow oven at peak temperature of 230° C.; and subjecting the blended composition to a subsequent post cure for 60 minutes at 160° C.

Glass transition temperature (Tg) was determined by non-isothermal DSC experiments performed with Differential Scanning Calorimeter (DSC) TA Instruments Q100 system. Approximately 10 mg samples of the underfill material were sealed in aluminum hermetic pans. The sample was heated with rate of 30° C./min from room temperature to 300° C. The heat flow during a curing was recorded. Tg was determined based on the second heating cycle of the same sample. Tg and CTE of the cured underfill materials were determined by Thermal Mechanical Analyzer (TMA) TMA7 from Perkin Elmer.

The solder fluxing test was performed using clean copper-laminated FR-4 board. A drop (0.2 g) of each blended formulation was dispensed on the copper laminate and a few solder balls (from about 2 to about 20) were placed inside the drop. Subsequently, the drop was covered with a glass slide and the copper plate was passed through a reflow oven at a peak temperature of 230° C. The solder balls spread and coalescence was examined under an optical microscope. The following scale was used to rate ability to flux:
1—no change in the shape of solder balls
2—solder starts to collapse
3—solder balls are collapsed but do not coalesce
4—solder balls are collapsed and some coalescent is observed
5—solder balls are collapsed and complete coalescent is observed

Table 1 below illustrates the capability of the no-flow underfill based upon UVR6105 resin, anhydride and hydroxyl group containing compound to flux.

TABLE 1

| | 1A | 1B | 1C | 1D |
|---|---|---|---|---|
| Components | | | | |
| UVR6105 | 5 | 5 | 5 | 5 |
| Fused Silica - FB-5LDX | | | 5 | 5 |
| MHHPA | 4.8 | 4.8 | 4.8 | 4.8 |
| Al(acac)₃/g | 0.1 | 0.02 | 0.1 | 0.02 |
| Optional Reagents | | | | |
| UVR6000 | 0.66 | | 0.66 | |
| Glycerol | | 0.22 | | 0.22 |
| Fluxing | 2 | 5 | 1 | 1 |
| Tg (TMA)/° C. | 175 | ND | 170 | ND |
| CTE (TMA)/ppm/° C. | 69 | ND | 42 | ND |

UVR 6000 is 3-ethyl-3-hydroxy methyl oxetane, an oxetane diluent commercially available from Dow Chemical Company

As can be seen in Table 1, the formulation with a high concentration of Al(acac)₃ (1A) cured too fast, with marginal fluxing. The incorporation of micron-sized fused silica (FB-5LDX from Denka) inhibited fluxing and reduces CTE from about 70 ppm/° C. (unfilled encapsulant) to about 42 ppm/° C.

Table 2 below illustrates the capability of the novel no-flow underfill based upon Resin 1 and Resin 2 to flux. Effect of type of functionalized colloidal silica on fluxing properties of underfill material.

TABLE 2

| | 2A | 2B | 2C | 2D |
|---|---|---|---|---|
| Components | | | | |
| Resin 1 | 10 | 10 | | |
| Resin 2 | | | 10 | 10 |
| MHHPA | 4.8 | 4.8 | 4.8 | 4.8 |
| Catalyst Type | Al(acac)3 | Al(acac)3 | Al(acac)3 | Al(acac)3 |
| Catalyst Amount/ | 0.02 | 0.02 | 0.02 | 0.02 |
| Optional Reagents | | | | |
| UVR6000 | 0.66 | | 0.66 | |
| Glycerol | | 0.22 | | 0.22 |
| Fluxing | 4 | 3 | 5 | 4 |
| Tg (TMA)/° C. | 156 | ND | 152 | 188 |
| CTE (TMA)/ppm/° C. | 50 | ND | 42 | 40 |

Formulations containing functionalized colloidal silica showed flux of solder. Combination of capped functionalized colloidal silica (Resin 2) and Al(acac)₃ had better stability at room temperature, better fluxing and lower CTE.

Table 3 below illustrates the capability of the novel no-flow underfill based upon Resin 1 to flux and also demonstrates the effect of catalyst on fluxing properties of the underfill material. The dispersions as tested are referred to as Encapsulants 3A-3G in Table 3.

TABLE 3

| Components | 3A | 3B | 3C | 3D | 3E | 3F | 3G |
|---|---|---|---|---|---|---|---|
| Resin 1/g | 5 | 5 | 5 | 5 | 5 | 5 | 5 |
| MHHPA/g | 2.33 | 2.33 | 2.33 | 2.33 | 2.33 | 2.33 | 2.33 |
| Catalyst Type | Al(acac)₃ | Tin | DBTDL | DY- | P(Ph)₃ | Polycat | none |
| | | Octoate | | 070US | | SA-1 | |
| Catalyst Amount/g | 0.025 | 0.025 | 0.025 | 0.025 | 0.025 | 0.022 | none |
| Fluxing | 3 | 1 | 5 | 1 | 4 | 5 | 5 |
| Tg (DSC) | 90 | ND | 141 | 197 | 198 | 181 | 120 |

Al(acac)₃ - Aldrich
Tin Octoate - Aldrich
DBTDL - DibutylTin Dilaurate (GE Silicones)
DY 070 US - N-methyl Imidazole (Ciba)
PPh₃ - Aldrich
Polycat ® SA-1 - phenolic complex of DBU (Air Products)

As can be seen from Table 3, the best fluxing and highest glass transition temperature was reached in the presence of Polycat® SA-1 and PPh₃ as catalyst. The uncatalyzed formulation of FCS and formulation catalyzed with DBTDL fluxed solder balls during reflow but the observed Tg was lower.

As can be seen, the formulation based on Resin 1 with MHHPA showed fluxing without any catalysts, but the resin had lower Tg after reflow. (Formulation UVR6105/MHHPA did not flux well under these conditions).

Table 4 below illustrates the capability of the novel no-flow underfill based upon Resin 1 to flux and the effect of the concentration of catalyst (Polycat® SA-1, from Air Products) on the fluxing properties of the no-flow underfill material. The dispersions as tested are referred to as Encapsulants 4A-4F in Table 4.

TABLE 4

| Components | 4A | 4B | 4C | 4D | 4E | 4F |
|---|---|---|---|---|---|---|
| Resin 1/g | 5 | 5 | 5 | 5 | 5 | 5 |
| MHHPA/g | 2.33 | 2.33 | 2.33 | 2.33 | 2.33 | 2.33 |
| Catalyst Type | Polycat- | Polycat- | Polycat- | Polycat- | Polycat- | Polycat- |
| | SA1 | SA1 | SA1 | SA1 | SA1 | SA1 |
| wt % Catalyst | 2 | 1.000 | 0.5 | 0.3 | 0.2 | 0.1 |
| Fluxing | 1 | 1.000 | 1 | 3 | 5 | 5 |
| Tg (DSC)/° C. | 185 | 174.67 | 192.82 | 185.43 | 176.03 | 181.15 |
| CTE (TMA) | 45 | 48 | ND | 46 | 46.5 | ND |
| ppm/° C. | | | | | | |

As can be seen from Table 4, a high concentration of Polycat SA-1 promoted too fast a cure and no fluxing was observed. Only formulations with a Polycat SA-1 concentration below 0.3 wt % showed fluxing of solder balls. All encapsulants 4A-4F have low CTE, below 50 ppm.

### EXAMPLE 6

Resin 1 and 2 were then utilized to form an underfill composition by adding MHHPA, PPh₃ as a catalyst, and both fluxing and Tg were determined. Tg was determined by DSC. The amounts of the components in the no-flow compositions and the observed fluxing and Tg are set forth below in Table 5.

TABLE 5

| Components | 5A | 5B | 5C | 5D |
|---|---|---|---|---|
| Resin 2/g | 5 | 5 | | |
| Resin 1/g | | | 5 | 5 |
| MHHPA/g | 2.33 | 2.33 | 2.33 | 2.33 |
| Catalyst Type | PPh₃ | PPh₃ | PPh₃ | PPh₃ |
| wt % Catalyst | 0.5 | 0.25 | 0.5 | 0.25 |
| Fluxing | 2 | 4 | 3 | 4 |
| Tg (DSC)/° C. | 179 | 175 | 178.7 | 157.8 |

### EXAMPLE 7

Resin 1, 2 and 3 were then utilized to form an underfill composition by adding MHHPA and catalyst. Fluxing, CTE and Tg were determined. Tg and CTE were determined by TMA. The amounts of the components in the no-flow compositions and the observed fluxing, CTE and Tg are set forth below in Table 6.

TABLE 6

| Components | 6A | 6B | 6C |
|---|---|---|---|
| Resin 3/g | 5 | 5 | 5 |
| MHHPA/g | 2.08 | 2.08 | 2.08 |
| Catalyst Type | DBTDL | Al(acac)₃ | Polycat-SA1 |
| wt % Catalyst | 0.2 | 0.2 | 0.2 |
| Fluxing | 4.5 | 1 | 4 |
| Tg (DSC)/° C. | 142 | ND | 156 |
| CTE (TMA) | 46 | ND | 44 |
| ppm/° C. | | | |

As is apparent from the above data, not all formulations with functional colloidal silica show good fluxing. Catalyst selection is important to maximize fluxing, Tg and CTE, and catalyst concentration has to be optimized to maximize fluxing. For example, formulations with a high concentration of PPh₃ (above 0.3 wt %) did not show any acceptable fluxing.

Other components, such as adhesion promoters, toughening additives, and aliphatic alcohols also affect fluxing properties.

While the disclosure has been illustrated and described in typical embodiments, it is not intended to be limited to the details shown, since various modifications and substitutions can be made without departing in any way from the spirit of the present disclosure. As such, further modifications and equivalents of the disclosure herein disclosed may occur to persons skilled in the art using no more than routine experimentation, and all such modifications and equivalents are believed to be within the spirit and scope of the disclosure as defined by the following claims.

1. A composition comprising an epoxy resin in combination with epoxy hardener and a filler of a functionalized colloidal silica wherein the colloidal silica is functionalized with an organoalkoxysilane and has a particle size ranging from about 1 nm to about 250 nm.

2. The composition in accordance with claim 1, wherein the epoxy resin comprises a cycloaliphatic epoxy monomer, an aliphatic epoxy monomer, an aromatic epoxy monomer, a silicone epoxy monomer, or combinations thereof.

3. The composition in accordance with claim 1, further comprising an epoxy monomer having two or more functionalities.

4. The composition in accordance with claim 3, wherein the epoxy monomer is selected from the group consisting of 3-cyclohexenylmethyl -3-cyclohexenylcarboxylate diepoxide, bisphenol-A epoxy resins, bisphenol-F epoxy resins or combinations thereof.

5. The composition in accordance with claim 1, wherein the organoalkoxysilane comprises phenyltrimethoxysilane.

6. The composition in accordance with claim 1, wherein the epoxy hardener comprises an anhydride curing agent, a phenolic resin, an amine epoxy hardener, or combinations thereof.

7. The composition in accordance with claim 6, wherein the epoxy hardener comprises an anhydride curing agent.

8. The composition in accordance with claim 7, wherein the anhydride curing agent is selected from the group consisting of methylhexahydrophthalic anhydride (MHHPA), methyltetrahydrophthalic anhydride, 1,2-cyclohexanedicarboxylic anhydride, bicyclo[2.2.1]hept-5-ene-2,3-dicarboxylic anhydride, methylbicyclo[2.2.1]hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and mixtures thereof.

9. The composition in accordance with claim 7, wherein the anhydride curing agent is methylhexahydrophthalic anhydride.

10. The composition in accordance with claim 1, further comprising a cure catalyst selected from the group consisting of amines, phosphines, metal salts, salts of nitrogen-containing compounds, and combinations thereof.

11. The composition in accordance with claim 10, wherein the cure catalyst comprises a salt of a nitrogen-containing compound.

12. The composition in accordance with claim 1, further comprising a hydroxyl-containing monomer selected from the group consisting of alcohols, alkane diols, glycerol, and phenols.

13. The composition in accordance with claim 1, wherein the colloidal silica is subsequently functionalized with at least one capping agent.

14. The composition in accordance with claim 13, wherein the capping agent comprises a silylating agent.

15. The composition in accordance with claim 14, wherein the silylating agent comprises hexamethyldisilazane.

16. The composition in accordance with claim 13, wherein at least 10% of free hydroxyl groups on the functionalized colloidal silica are capped.

17. The composition in accordance with claim 13, wherein at least 20% of free hydroxyl groups on the functionalized colloidal silica are capped.

18. An underfill composition comprising an epoxy resin in combination with epoxy hardener and a filler of a functionalized colloidal silica wherein the colloidal silica is functionalized with phenyltrimethoxysilane and has a particle size ranging from about 1 nm to about 250 nm.

19. The underfill composition in accordance with claim 18, wherein the epoxy resin comprises a cycloaliphatic epoxy monomer, an aliphatic epoxy monomer, an aromatic epoxy monomer, a silicone epoxy monomer, or combinations thereof.

20. The underfill composition in accordance with claim 19, wherein the epoxy monomer is 3-cyclohexenylmethyl-3-cyclohexenylcarboxylate diepoxide, bisphenol-A epoxy resins, bisphenol-F epoxy resins or combinations thereof.

21. The underfill composition in accordance with claim 18, wherein the epoxy hardener comprises an anhydride curing agent, a phenolic resin, an amine epoxy hardener, or combinations thereof.

22. The underfill composition in accordance with claim 21, wherein the epoxy hardener comprises an anhydride curing agent.

23. The underfill composition in accordance with claim 22, wherein the anhydride curing agent is selected from the group consisting of methylhexahydrophthalic anhydride (MHHPA), methyltetrahydrophthalic anhydride, 1,2-cyclohexanedicarboxylic anhydride, bicyclo[2.2.]hept-5-ene-2,3-dicarboxylic anhydride, methylbicyclo[2.2.1]hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and mixtures thereof.

24. The underfill composition in accordance with claim 22, wherein the anhydride curing agent is methylhexahydrophthalic anhydride.

25. The underfill composition in accordance with claim 18, further comprising a cure catalyst selected from the group consisting of amines, phosphines, metal salts, salts of nitrogen-containing compounds, and combinations thereof.

26. The underfill composition in accordance with claim 25, wherein the cure catalyst comprises salts of a nitrogen-containing compound.

27. The underfill composition in accordance with claim 18, further comprising a hydroxyl-containing monomer selected from the group consisting of alcohols, alkane diols, glycerol, and phenols.

28. The underfill composition in accordance with claim 18 wherein the colloidal silica is subsequently functionalized with at least one capping agent.

29. The underfill composition in accordance with claim 28, wherein the capping agent comprises a silylating agent.

30. The underfill composition in accordance with claim 29, wherein the silylating agent comprises hexamethyldisilazane.

31. The underfill composition in accordance with claim 28, wherein at least 10% of free hydroxyl groups on the functionalized colloidal silica are capped.

32. The underfill composition in accordance with claim 28, wherein at least 20% of free hydroxyl groups on the functionalized colloidal silica are capped.

33. A packaged solid state device comprising:
a package;
a chip; and
an encapsulant comprising an epoxy resin in combination with an epoxy hardener and a filler of a functionalized colloidal silica wherein the colloidal silica is functionalized with at least one organoalkoxysilane functionalization agent and has a particle size ranging from about 1 nm to about 250 nm.

34. The packaged solid state device in accordance with claim 33, wherein the epoxy resin comprises a cycloaliphatic epoxy monomer, an aliphatic epoxy monomer, an aromatic epoxy monomer, a silicone epoxy monomer, or combinations thereof.

35. The packaged solid state device in accordance with claim 34, wherein the epoxy monomer is 3-cyclohexenylmethyl-3-cyclohexenylcarboxylate diepoxide, bisphenol-A epoxy resins, bisphenol-F epoxy resins or combinations thereof.

36. The packaged solid state device in accordance with claim 33, wherein the epoxy hardener comprises an anhydride curing agent, a phenolic resin, an amine epoxy hardener, or combinations thereof.

37. The packaged solid state device in accordance with claim 36, wherein the epoxy hardener comprises an anhydride curing agent.

38. The packaged solid state device in accordance with claim 37, wherein the anhydride curing agent is selected from the group consisting of methylhexahydrophthalic anhydride (MHHPA), methyltetrahydrophthalic anhydride, 1,2-cyclohexanedicarboxylic anhydride, bicyclo[2.2.1]hept-5-ene-2,3-dicarboxylic anhydride, methylbicyclo[2.2.1]hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and mixtures thereof.

39. The packaged solid state device in accordance with claim 37, wherein the anhydride curing agent is methylhexahydrophthalic anhydride.

40. The packaged solid state device in accordance with claim 33, further comprising a cure catalyst selected from the group consisting of amines, phosphines, metal salts, salts of nitrogen-containing compounds, and combinations thereof.

41. The packaged solid state device in accordance with claim 40, wherein the cure catalyst comprises salts of a nitrogen-containing compound.

42. The packaged solid state device in accordance with claim 33, further comprising a hydroxyl-containing monomer selected from the group consisting of alcohols, alkane diols, glycerol, and phenols.

43. The packaged solid state device in accordance with claim 33, wherein the colloidal silica is subsequently functionalized with at least one capping agent.

44. The packaged solid state device in accordance with claim 43, wherein the capping agent comprises a silylating agent.

45. The packaged solid state device in accordance with claim 44, wherein the silylating agent comprises hexamethyldisilazane.

46. The packaged solid state device in accordance with claim 43, wherein at least 10% of free hydroxyl groups on the functionalized colloidal silica are capped.

47. The packaged solid state device in accordance with claim 43, wherein at least 20% of free hydroxyl groups on the functionalized colloidal silica are capped.
